(19) United States
(12) Patent Application Publication
(10) Pub. No.: US 2008/0119098 A1
(43) Pub. Date: May 22, 2008

(54) Atomic layer deposition on fibrous materials

(76) Inventors: Igor Palley, Madison, NJ (US); Chien-Wei Li, Livingston, NJ (US); Ashok Bhatnagar, Richmond, VA (US); David A. Hurst, Richmond, VA (US); Jingyu Lao, Clifton Park, NY (US)

Correspondence Address: Roberts & Roberts, L.L.P.;Attorneys at Law, P.O. Box 484, Princeton, NJ, 08542-0484, US

(21) Appl. No.: 11/602,830

(22) Filed: Nov. 21, 2006

(51) Int. Cl. D04H 13/00; C23C 16/44; B32B 5/02; B32B 27/02

(52) U.S. Cl. 442/64; 427/255.24; 428/221; 442/164

(57) ABSTRACT

A method for depositing an encapsulation layer onto a surface of polymeric fibers and ballistic resistant fabrics. More particularly, the atomic layer deposition of materials onto non-semiconductive polymeric fibers and fabrics, and to fabrics having an conformal encapsulation layer that has been applied by atomic layer deposition.

### BACKGROUND OF THE INVENTION

1. Field of the Invention

The invention relates to a method for depositing an encapsulation layer onto a surface of polymeric fibers and ballistic resistant fabrics. More particularly, the invention pertains to the atomic layer deposition of materials onto non-semiconductive polymeric fibers and fabrics, and to fabrics having a conformal encapsulation layer that has been applied by atomic layer deposition.

2. Description of the Related Art

Atomic layer deposition (ALD) is a well-known technique for depositing highly dense films of various materials onto the surfaces of various substrates. See, for example, U.S. Pat. No. 7,128,787 which teaches an ALD method utilizing a semiconductor substrate. ALD processes are characterized by two self-limiting chemical reactions of vaporized precursor materials on a substrate surface in a repeated alternate deposition sequence. The process is conducted within a deposition chamber or tube that is typically maintained at sub-atmospheric pressure and at varied deposition temperatures. A successive layer-by-layer buildup of materials is performed by the chemisorption of molecular precursors at the substrate surface. In an exemplary process, a first vapor precursor is fed into a deposition chamber causing molecules of the first precursor to chemically react with molecules on the substrate surface. After the flow of the first precursor is terminated, and an inert purge gas is flowed through the chamber effective to remove any remaining first precursor which is not chemisorbing to the substrate. Subsequently, a second vapor precursor different from the first is fed into the chamber effective to chemically react with the chemisorbed molecules of the first precursor, forming a first monolayer of a reaction product on the substrate. When this process is repeated, the first vaporized precursor will react with surface molecules of the formed monolayer, and the alternating charging of the vapor precursors into the reaction vessel will form successive monolayers until a desired thickness of the deposited material has been formed on the substrate. ALD offers a high degree of control over film composition and thickness, and deposited layers have large area uniformity and 3D conformality.

Atomic layer deposition is commonly used in the integrated circuit industry to apply inorganic coatings on semiconductor substrates to enhance the surface properties of the substrate. It is a particular method of choice where it is desirable to conformally deposit materials over the surfaces of high aspect ratio features on semiconductor substrates. See, for example, U.S. Pat. Nos. 7,119,034, 7,105,444 and 7,087,482, among many others. ALD has also been used in the production of displays, optical coatings, micro-electro-mechanical systems (MEMS), nano-electro-mechanical systems (NEMS), for organic light emitting diode (OLED) passivation and antireflective coatings, coatings on particles, as well as other nanotechnology arts.

The present invention presents a new application, where an encapsulation layer is deposited onto a surface of one or more polymeric fibers by ALD, particularly onto non-semiconductive, high strength fibers used to form ballistic resistant fabrics. Ballistic resistant articles containing high strength fibers that have excellent properties against projectiles are well known. Articles such as bullet resistant vests, helmets, vehicle panels and structural members of military equipment are typically made from fabrics comprising high strength fibers, such as SPECTRA® polyethylene fibers or Kevlar® aramid fibers. For many applications, such as vests or parts of vests, the fibers may be used in a woven or knitted fabric. For other applications, the fibers may be encapsulated or embedded in a polymeric matrix material and formed into non-woven fabrics. For example, U.S. Pat. Nos. 4,403,012, 4,457,985, 4,613,535, 4,623,574, 4,650,710, 4,737,402, 4,748,064, 5,552,208, 5,587,230, 6,642,159, 6,841,492, 6,846,758, all of which are incorporated herein by reference, describe ballistic resistant composites which include high strength fibers made from materials such as extended chain ultra-high molecular weight polyethylene. These composites display varying degrees of resistance to penetration by high speed impact from projectiles such as bullets, shells, shrapnel and the like.

It has been unexpectedly discovered that the application of a thin encapsulation layer of various materials onto non-semiconductive, high strength polymeric fibers improves properties such as fiber mobility (when engaged by a projectile), fiber thermal conductivity and heat dissipation, protection of fiber load bearing properties at a projectile contact area, fiber surface hardness and resistance to environmental degradation, while maintaining fiber flexibility.

### SUMMARY OF THE INVENTION

The invention provides a method which comprises depositing an encapsulation layer onto a surface of one or more polymeric fibers by atomic layer deposition.

The invention also provides a fabric comprising a plurality of polymeric fibers arranged in an array, said fibers having an atomic layer deposited encapsulation layer thereon.

### BRIEF DESCRIPTION OF THE DRAWING

FIG. 1 is a graph illustrating the effect of a Ta₂O₅ ALD coating on fiber pullout force and energy for three different coating weights and an uncoated control sample, based on the 45 degree fiber pullout test.

FIG. 2 is a graph illustrating the effect of a Al₂O₃ ALD coating on fiber pullout force and energy for two different coating weights and an uncoated control sample, based on the 45 degree fiber pullout test.

FIG. 3 is a scanning electron microscope image of a cross-section of an ALD Al₂O₃ coated woven fabric, showing an Al₂O₃ coating on an individual fiber.

### DETAILED DESCRIPTION OF THE INVENTION

The invention provides fibers, fabrics and articles that have an encapsulation layer deposited thereon, which encapsulation layer is deposited by atomic layer deposition techniques. As used herein, a “fiber” is an elongate body the length dimension of which is much greater than the transverse dimensions of width and thickness. The cross-sections of fibers for use in this invention may vary widely. They may be circular, flat or oblong in cross-section. Accordingly, the term fiber includes filaments, ribbons, strips and the like having regular or irregular cross-section. They may also be of irregular or regular multi-lobal cross-section having one or more regular or irregular lobes projecting from the linear or longitudinal axis of the fibers. It is preferred that the fibers are single lobed and have a substantially circular cross-section.

The ALD process may be conducted on a single polymeric fiber or a plurality of polymeric fibers. A plurality of fibers may be present in the form of a woven fabric, a non-woven fabric or a yarn, where a yarn is defined herein as a strand consisting of multiple fibers. Further, in embodiments including a plurality of fibers, ALD may be conducted either before the fibers are arranged into a fabric or yarn, or after the fibers are arranged into a fabric or yarn.

The fibers of the invention may comprise any polymeric fiber type. Typically, fibers useful for the formation of ballistic resistant fabrics are non-semiconductive. Most preferably, the fibers comprise high strength, high tensile modulus fibers which are useful for the formation of ballistic resistant materials and articles. As used herein, a “high-strength, high tensile modulus fiber” is one which has a preferred tenacity of at least about 7 g/denier or more, a preferred tensile modulus of at least about 150 g/denier or more, and preferably an energy-to-break of at least about 8 J/g or more, each both as measured by ASTM D2256. As used herein, the term “denier” refers to the unit of linear density, equal to the mass in grams per 9000 meters of fiber or yarn. As used herein, the term “tenacity” refers to the tensile stress expressed as force (grams) per unit linear density (denier) of an unstressed specimen. The “initial modulus” of a fiber is the property of a material representative of its resistance to deformation. The term “tensile modulus” refers to the ratio of the change in tenacity, expressed in grams-force per denier (g/d) to the change in strain, expressed as a fraction of the original fiber length (in/in).

The polymer forming the fibers may be thermoplastic or thermosetting, and are preferably high-strength, high tensile modulus fibers suitable for the manufacture of ballistic resistant fabrics. Particularly suitable high-strength, high tensile modulus fiber materials that are particularly suitable for the formation of ballistic resistant materials and articles include polyolefin fibers including high density and low density polyethylene. Particularly preferred are extended chain polyolefin fibers, such as highly oriented, high molecular weight polyethylene fibers, particularly ultra-high molecular weight polyethylene fibers and polypropylene fibers, particularly ultra-high molecular weight polypropylene fibers. Also suitable are aramid fibers, particularly para-aramid fibers, polyamide fibers, polyimide fibers, polyamidimide fibers, polycarbonate polybutylene fibers, polystyrene fibers, polyester fibers such as polyethylene terephthalate fibers, polyethylene naphthalate fibers, polycarbonate fibers, polyacrylate fibers, polybutadiene fibers, polyurethane fibers, extended chain polyvinyl alcohol fibers, fibers formed from fluoropolymers such as polytetrafluoroethylene (PTFE), epoxy fibers, phenolic resin polymeric fibers, polyvinyl chloride fibers, organosilicone polymeric fibers, extended chain polyacrylonitrile fibers, polybenzazole fibers, such as polybenzoxazole (PBO) and polybenzothiazole (PBT) fibers, liquid crystal copolyester fibers and rigid rod fibers such as M5® fibers. Also suitable for producing polymeric fibers are copolymers, block polymers and blends of the above materials. Not all of these fiber types are useful for the formation of ballistic resistant fabrics. The most preferred fiber types for ballistic resistant fabrics include polyethylene, particularly extended chain polyethylene fibers, aramid fibers, polybenzazole fibers, liquid crystal copolyester fibers, polypropylene fibers, particularly highly oriented extended chain polypropylene fibers, polyvinyl alcohol fibers, polyacrylonitrile fibers and rigid rod fibers, particularly M5® fibers.

In the case of polyethylene, preferred fibers are extended chain polyethylenes having molecular weights of at least 500,000, preferably at least one million and more preferably between two million and five million. Such extended chain polyethylene (ECPE) fibers may be grown in solution spinning processes such as described in U.S. Pat. Nos. 4,137,394 or 4,356,138, which are incorporated herein by reference, or may be spun from a solution to form a gel structure, such as described in U.S. Pat. Nos. 4,551,296 and 5,006,390, which are also incorporated herein by reference. A particularly preferred fiber type for use in the invention are polyethylene fibers sold under the trademark SPECTRA® from Honeywell International Inc. SPECTRA® fibers are well known in the art and are described, for example, in U.S. Pat. Nos. 4,623,547 and 4,748,064.

Also particularly preferred are aramid (aromatic polyamide) or para-aramid fibers. Such are commercially available and are described, for example, in U.S. Pat. No. 3,671,542. For example, useful poly(p-phenylene terephthalamide) filaments are produced commercially by Dupont corporation under the trade name of KEVLAR®. Also useful in the practice of this invention are poly(m-phenylene isophthalamide) fibers produced commercially by Dupont under the trade name NOMEX® and fibers produced commercially by Teijin under the trade name TWARON®.

Suitable polybenzazole fibers for the practice of this invention are commercially available and are disclosed for example in U.S. Pat. Nos. 5,286,833, 5,296,185, 5,356,584, 5,534,205 and 6,040,050, each of which are incorporated herein by reference. Preferred polybenzazole fibers are ZYLON® brand fibers from Toyobo Co. Suitable liquid crystal copolyester fibers for the practice of this invention are commercially available and are disclosed, for example, in U.S. Pat. Nos. 3,975,487; 4,118,372 and 4,161,470, each of which is incorporated herein by reference.

Suitable polypropylene fibers include highly oriented extended chain polypropylene (ECPP) fibers as described in U.S. Pat. No. 4,413,110, which is incorporated herein by reference. Suitable polyvinyl alcohol (PV-OH) fibers are described, for example, in U.S. Pat. Nos. 4,440,711 and 4,599,267 which are incorporated herein by reference. Suitable polyacrylonitrile (PAN) fibers are disclosed, for example, in U.S. Pat. No. 4,535,027, which is incorporated herein by reference. Each of these fiber types is conventionally known and are widely commercially available.

The other suitable fiber types for use in the present invention include rigid rod fibers such as M5® fibers, and combinations of all the above materials, all of which are commercially available. For example, the fibrous layers may be formed from a combination of SPECTRA® fibers and Kevlar® fibers. M5® fibers are manufactured by Magellan Systems International of Richmond, Va. and are described, for example, in U.S. Pat. Nos. 5,674,969, 5,939,553, 5,945,537, and 6,040,478, each of which is incorporated herein by reference. Specifically preferred fibers include M5® fibers, polyethylene SPECTRA® fibers, and aramid Kevlar® fibers. The fibers may be of any suitable denier, such as, for example, 50 to about 3000 denier, more preferably from about 200 to 3000 denier, still more preferably from about 650 to about 2000 denier, and most preferably from about 800 to about 1500 denier. While these deniers are preferred for good ballistic resistance, ALD should increase the ballistic performance of all fabric types irrespective of fiber denier.

The most preferred fibers for the purposes of the invention are either high-strength, high tensile modulus extended chain polyethylene fibers or high-strength, high tensile modulus para-aramid fibers. As stated above, a high-strength, high tensile modulus fiber is one which has a preferred tenacity of about 7 g/denier or more, a preferred tensile modulus of about 150 g/denier or more and a preferred energy-to-break of about 8 J/g or more, each as measured by ASTM D2256. In the preferred embodiment of the invention, the tenacity of the fibers should be about 15 g/denier or more, preferably about 20 g/denier or more, more preferably about 25 g/denier or more and most preferably about 30 g/denier or more. The fibers of the invention also have a preferred tensile modulus of about 300 g/denier or more, more preferably about 400 g/denier or more, more preferably about 500 g/denier or more, more preferably about 1,000 g/denier or more and most preferably about 1,500 g/denier or more. The fibers of the invention also have a preferred energy-to-break of about 15 J/g or more, more preferably about 25 J/g or more, more preferably about 30 J/g or more and most preferably have an energy-to-break of about 40 J/g or more.

These combined high strength properties are obtainable by employing well known processes. U.S. Pat. Nos. 4,413,110, 4,440,711, 4,535,027, 4,457,985, 4,623,547 4,650,710 and 4,748,064 generally discuss the formation of preferred high strength, extended chain polyethylene fibers employed in the present invention. Such methods, including solution grown or gel fiber processes, are well known in the art. Methods of forming each of the other preferred fiber types, including para-aramid fibers, are also conventionally known in the art, and the fibers are commercially available.

The fibers useful in the ballistic resistant fabrics are preferably from about 50 denier to about 3000 denier. The selection is governed by considerations of ballistic effectiveness and cost. Finer fibers are more costly to manufacture and to weave, but can produce greater ballistic effectiveness per unit weight. The fibers are preferably from about 200 denier to about 3000 denier, more preferably from about 650 denier to about 1500 denier and most preferably from about 800 denier to about 1300 denier.

As stated above, in the process of the invention, the ALD process may be conducted on a single polymeric fiber, or a plurality of polymeric fibers. In the preferred embodiments of the invention, a plurality of fibers are present and are in the form of a woven fabric or a non-woven fabric. With regard to woven fabrics, while ALD may be conducted either before or after the fibers are woven, it is most preferred that ALD be conducted after fibers are woven into a fabric. With regard to non-woven fabrics, it is preferred that ALD be conducted before the fabrics are formed into a non-woven fabric.

As is well known in the art, atomic layer deposition may be conducted in a variety of different reaction vessels, using various different reaction precursors and purge gases. Reaction temperatures and pressures may vary depending on both the material being deposited as well as the substrate type. For the purposes of this invention, any known variation of atomic layer deposition may be conducted as long as it is sufficient to form a conformal encapsulation layer on the polymeric fibers without degrading the polymer. By “conformal” it is meant that the thickness of the coating is relatively uniform across the surface of the particle. The reactants can cover all surfaces of the substrate, even if those surfaces are not in the direct path of the precursors as they are brought into the reaction chamber. However, atomic layer deposition will only coat exposed substrate surfaces that can be reached by the precursor compositions. It should be understood that the term “encapsulation” may include embodiments where the surfaces of a woven or non-woven fabric are completely covered with one or more monolayers of the deposited material, but where less than 100% of the surface area of the individual fibers forming the fabric may be covered.

Atomic layer deposition is similar in chemistry to chemical vapor deposition (CVD), except that an ALD reaction essentially breaks the CVD reaction into two half-reactions, keeping the precursor materials separate during the reaction. ALD film growth is self-limited and based on surface reactions, which makes achieving atomic scale deposition control possible. ALD has an advantage over CVD in several areas, as ALD grown films are conformal, pin-hole free, and allows for extremely precise control of film thickness and achieves high uniformity.

In accordance with typical ALD methods, fibers and/or fiber fabrics are placed into a suitable reaction vessel, particularly a chamber or reaction tube that is capable of being evacuated and maintained at sub-atmospheric pressure. Most typically, the reaction is conducted under a vacuum. Examples of suitable of reactors used for the deposition of thin films include any commercially available ALD equipment, including F-120, F-120 SAT and PULSAR® reactors produced by ASM Microchemistry Ltd. of Finland, and the P400A made by Planar Systems Inc. of Finland. In addition to these ALD reactors, many other kinds of reactors capable for ALD growth of coatings, including rotary tube reactors and CVD reactors equipped with appropriate equipment and means for pulsing the precursors can be utilized.

Initially, the reactor vessel is preferably pumped down and back filled with an inert gas to purge the vessel of any impurities, while keeping the internal vessel pressure at about 13.33 Pa (0.1 Torr) to about 2666 Pa (20 Torr). Examples of suitable purge gases non-exclusively include nitrogen, argon and combinations thereof. In a thermally activated ALD reaction, the fibers and/or fiber fabrics are heated up to suitable deposition temperature, at about 0.1 Torr to about 20 Torr lowered pressure. A typical thermally activated ALD reaction is conducted at from about room temperature (approximately 20-25° C.) to about 400° C. At elevated temperatures, the polymer chains in the substrate are thermally agitated, exposing free radical carbon chains at the surface of the polymer, providing functional groups on the surface of the polymer for reaction with the ALD precursors and facilitating adsorption of the ALD precursors. Thus, conducting the ALD reaction sequences at elevated temperatures is desirable in some instances. For the purposes of this invention, it is important that the reactions are performed at a temperature below that at which the polymer degrades, melts, or softens enough to lose its physical shape. The temperature at which the ALD reactions are conducted herein is therefore generally below about 300° C., preferably below about 200° C., with the upper temperature limit being dependent on the particular polymer to be coated. Many non-semiconductive polymers useful herein degrade, melt or soften at temperatures about 200° C. to about 300° C. For the particularly preferred polymeric fibers described herein, the fibers and/or fiber fabrics are preferably heated up to about room temperature to about 200° C.

In an alternate method, instead of or together with being thermally activated, the ALD process may be plasma activated in a process known as plasma enhanced ALD, or PEALD. In PEALD, which is well known in the art, plasma introduction controls the reaction, while fibers can be heated or not heated. Common plasma types include direct plasma, remote plasma, high frequency AC plasma, RF plasma, microwave plasma or inductively coupled plasma. The plasma frequency can be from 0 Hz to about 2.5 GHz, and the energy density can be about 0.01 W/cm² to about 10 W/cm². The plasma pulse time can be from 0.1 to 50 seconds. In a PEALD process, the pressure of chamber is preferably between about 0.1 Torr to about 20 Torr and the fiber deposition temperature is between about room temperature to about 200° C. The plasma is turned on during the second precursor exposure step to activate the reaction between the adsorbed layer of the first precursor on the substrate and the forthcoming second precursor. Due to the plasma activation, PEALD can lower the deposition temperature and improve the adhesion of coated materials to the substrate.

Inside the reaction vessel, the fiber or fibers are then sequentially contacted with two reactive vapor reactants. Each reactant is introduced sequentially into the reaction vessel, typically together with an inert carrier gas. A first vapor precursor is pulsed into the reaction vessel in the gaseous phase and precursor molecules chemisorbs with reaction sites on the fiber and/or fabric surface (substrate) until the substrate surface is saturated by the first precursor with one layer of the precursor compound adsorbed onto the surface. Once saturated, the vessel is preferably cleared of any excess, unreacted first precursor by purging the excess out of the reaction vessel with an inert gas, preferably in combination with vacuum pump down. This may be done, for example, by subjecting the substrate to a high vacuum at about 10⁻⁵ torr or lower after each reaction step. This purging step may not be necessary with a plasma enhanced process. An evacuation step without any gas flowing in and with a full throttle valve open to pump may also be conducted instead of or together with the inert gas purge. Subsequently, a second vapor precursor reactant is pulsed into the vessel and onto the fibers and/or fabrics and reacts with the first precursor molecules that adsorbed on the fiber/fabric surfaces.

The precursors may be pulsed into the vessel with or without a carrier gas such as nitrogen, argon and hydrogen. Other example of precursor delivery includes dissolving the precursor into a predetermined liquid organic solvent to give a liquid solution, and then delivering the solution to a vaporizer where it is vaporized and the vapor is delivered to the substrate surface with or without the carrier gas. Suitable solvent types will vary depending on the precursor material and would be easily determined by one skilled in the art.

After reaction, the excess of the second vapor precursor reactant and any gaseous by-products of the surface reactions are preferably purged out of the reaction chamber. The steps of pulsing and purging are repeated in the indicated order until the desired thickness of the deposited thin film is reached. A preferred number of reaction cycles, where one cycle includes charging of both precursors into the reaction vessel, is from 2 to about 10,000 cycles, more preferably from about 2 to about 2000 reaction cycles, most preferably from about 50 to about 1000 reaction cycles, without regard to the material being deposited. In sum, the ALD method is based on controlled surface reactions of the precursor chemicals, depositing an encapsulation layer onto all exposed fiber or fabric surfaces in the reaction vessel.

Using a rotary tube reactor, the reactor comprises a hollow tube that contains the fibers or fabric. The tube reactor is held at an angle to the horizontal, and the substrate passes through the tube through gravitational action. The tube is rotated in order to evenly expose the substrate surfaces to the reactants. A tube reactor is particularly suitable for continuous operations. The reactants are introduced individually and sequentially through the tube, preferentially countercurrent to the direction of the substrate.

For the purposes of this invention, the materials to be deposited by atomic layer deposition to form an encapsulation layer non-exclusively include oxides including Al₂O₃, SiO₂, Ta₂O₅, ZrO₂, HfO₂, ZnO, TiO₂, MgO, Cr₂O₃, Co₂O₃, NiO, FeO, Ga₂O₃, GeO₂, V₂O₅, Y₂O₃, rare earth oxides, CaO, In₂O₃, SnO₂, PbO, MoO₃ and WO₃. Nitrides to be deposited include TiN, TaN, Si₃N₄, AlN, Hf₃N₄, Zr₃N₄, WNx (where x=0.1-2.0), BN, carbon nitride, and alloys and nanolaminates thereof. Carbides to be deposited include SiC, TiC, boron carbide, WC, W₂C, Fe₃C, TaC, HfC, ZrC, MoC, and alloys and nanolaminates thereof. Silicides to be deposited include NiSi, WSi₂, CoSi₂ and TiSi₂. Borides to be deposited include TiB₂, WB and MgB₂. Sulfides to be deposited include WS₂, MoS₂, copper sulfide, CaS₂, La₂S₃. Metals that may be deposited include Ru, Pt, Pd, Co, Ni, Fe, Mo, Cr, Sn, W and Cu. Fluorides to be deposited include CaF₂, SrS, SrF₂, ZnF₂; and ternary compounds to be deposited include TiCN, TiON, tungsten carbonitride, titanium aluminum nitride, SrTiO₃, La₂O₂S and LaAlO₃. Combinations of the above materials may be deposited as alloys or as nanolaminates, where a nanolaminate is a thin film composed of a series of alternating sub-layers with different compositions, such as Al₂O₃ and Ta₂O₅, each being deposited by ALD with their corresponding first and second precursors. Useful alloys non-exclusively include Hf—Si—O, Hf—Al—O, Ru—Cu, Ta—Al—O and Ti—Al—O, which alloys can be formed by co-pulsing or mixing two metal containing precursors. Useful nanolaminates non-exclusively include HfO₂—Al₂O₃, HfO₂—SiO₂, Ru—Pt, ZrO₂—Al₂O₃, ZrO₂—SiO₂ and Al₂O₃—SiO₂. In the most preferred embodiments of the invention, the encapsulation layer or layers comprise silicon oxide, titanium oxide, aluminum oxide, tantalum oxide, hafnium oxide, zirconium oxide, titanium aluminate, titanium silicate, hafnium aluminate, hafnium silicate, zirconium aluminate, zirconium silicate, boron nitride or a combination thereof. As is well known in the art, these materials are deposited as the reaction product from the reaction of a first vapor precursor with a second vapor precursor. As stated above, molecules of the first precursor react with and are chemisorbed by and the substrate at its surface, and molecules of the second precursor react with molecules of the first precursor. Useful vaporizable first precursors non-exclusively include trimethylaluminum (TMA), titanium isopropyloxide, pentakis(dimethylamino)tantalum, tetrakis(diethylamido)hafnium(IV), tetrakis(dimethylamido)hafnium(IV), tetrakis(ethylmethylamido)hafnium(IV), hafnium(IV) chloride, hafnium(IV) tert-butoxide, diethylaluminum ethoxide, aluminum sec-butoxide, tris(diethylamido)aluminum, tris(ethylmethylamido)aluminum, bis(N,N′-di-tert-butylacetamidinato)iron(II), bis(N,N′-diisopropylacetamidinato)nickel(II), bis(N,N′-diisopropylacetamidinato)cobalt(II), bis(cyclopentadienyl)magnesium(II), bis(pentamethylcyclopentadienyl)magnesium(II), molybdenum hexacarbonyl, molybdenum hexafluoride, bis(methylcyclopentadienyl)nickel(II), dimethoxydimethylsilane, methylsilane, disilane, 2,4,6,8-tetramethylcyclotetrasiloxane, tris(tert-butyoxy)silanol, tris(diethylamido)(tert-butylimido)tantalum(V), bis(diethylamino)bis(diisopropylamino) titanium(IV), tetrakis(diethylamido)titanium(IV), tetrakis(dimethylamido)titanium(IV), tetrakis(ethylmethylamido) titanium(IV), bis(tert-butylimido)bis(dimethylamido) tungsten(VI), tungsten hexacarbonyl, tris(N,N-bis(trimethylsilyl)amide) yttrium(III), yttrium(III) tris(2,2,6,6-tetramethyl-3,5-heptanedionate), tris(cyclopentadienyl)yttrium, tris(butylcyclopentadienyl)yttrium, diethylzinc, tetrakis(diethylamido)zirconium(IV), tetrakis(dimethylamido) zirconium(IV), tetrakis(ethylmethylamido) zirconium(IV), zirconium tetrakis(2,2,6,6-tetramethyl-3,5-heptanedionate), bis(pentamethylcyclopentadienyl)cobalt(II), bis(ethylcyclopentadienyl)cobalt(II), cobalt tris(2,2,6,6-tetramethyl-3,5-heptanedionate), bis(pentamethylcyclopentadienyl)chromium(II), bis(cyclopentadienyl)vanadium(II), vanadyl acetylacetonate, tungsten hexafluoride, bis(cyclopentadienyl)tungsten dichloride, bis(yclopentadienyl)tungsten dihydride, SiCl₄, AlCl₃, TaI₅, TaF₅, SnI₄, chromyl chloride, copper(II) dialkylamino-2-propoxides, tris[bis(trimethylsilyl)amido]lanthanum, Ga(N₃)₂Et, TiCl₄, praseodymium alkoxide, Pt(C₂H₅C₅H₄)(CH₃)₃, Pt(acac)₂ (“acac”=acetylacetonate ligand), molybdenum(V) chloride, zinc bis(O-ethylxanthate), CuII(tmhd)₂ (tmhd=2, 2, 6, 6-tetramethyl-3,5-heptanedionate), bis(cyclopentadienyl) ruthenium(II) (commonly referred to as Ru(Cp)₂), bis(ethyl cyclopentadienyl) ruthenium(II) (commonly referred to as Ru(EtCp)₂), (2,4-dimethylpentadienyl)(ethylcyclopentadienyl)Ru, tris(2,4-pentanedionato)iridium, Ru(thd)₃ (thd=2, 2, 6, 6-tetramethyl-3,5-heptanedionate), (methylcyclopentadienyl)trimethylplatinum, hexafluoroacetylacetonato(trimethylsilylethylene)copper, Cu(II) (diketiminate)₂, cyclopentadienylallylnickel, Rh(acetylacetonato)₃, Pd(hexafluoroacetonylacetonate)₂, Pd(2,2,6,6-tetramethyl-3,5-heptanedione)₂, methylcyclopentadienyltrimethylplatnium, Ga₂(NMe₂)₆, [(CH₃]₂GaNH₃]₃, Er(thd)₃, bis(2,2,6,6-tetramethyl-3,5-heptanedionato)Sr, Pb(thd)₂, Pb(C₂H₅)₄, (CpCH₃)₃Gd, bis-dipivaloylmethanato-barium (Ba(thd)₂) and InCl₃, rare earth precursors with β-diketonate-type ligands, including β-diketonate-type Ln(thd)₃ materials, which include Gd(thd)₃ and Er(thd)₃, as well as thd mixed with other ligands.

Of these, the following are preferred: trimethyaluminum, titanium isopropyloxide, pentakis(dimethylamino)tantalum, tetrakis(diethylamido)hafnium(IV), tetrakis(dimethylamido)hafnium(IV), tetrakis(ethylmethylamido)hafnium(IV), hafnium(IV) chloride, tris(diethylamido)aluminum, tris(ethylmethylamido)aluminum, bis(N,N′-di-tert-butylacetamidinato)iron(II), bis(N,N′-diisopropylacetamidinato)nickel(II), bis(N,N′-diisopropylacetamidinato)cobalt(II), bis(cyclopentadienyl)magnesium(II), bis(methylcyclopentadienyl)nickel(II), dimethoxydimethylsilane, methylsilane, disilane, tris(tert-butyoxy)silanol, tris(diethylamido)(tert-butylimido)tantalum(V), bis(diethylamino)bis(diisopropylamino)titanium(IV), tetrakis(diethylamido)titanium(IV), tetrakis(dimethylamido)titanium(IV), tetrakis(ethylmethylamido)titanium(IV), bis(tert-butylimido)bis(dimethylamido) tungsten(VI), yttrium(III) tris(2,2,6,6-tetramethyl-3,5-heptanedionate), tris(cyclopentadienyl)yttrium, tris(butylcyclopentadienyl)yttrium, diethylzinc, tetrakis(diethylamido)zirconium(IV), tetrakis(dimethylamido) zirconium(IV), tetrakis(ethylmethylamido) zirconium(IV), zirconium tetrakis(2,2,6,6-tetramethyl-3,5-heptanedionate), bis(pentamethylcyclopentadienyl)cobalt(II), bis(ethylcyclopentadienyl)cobalt(II), bis(pentamethylcyclopentadienyl)chromium(II), bis(cyclopentadienyl)vanadium(II), vanadyl acetylacetonate, tungsten hexafluoride, tungsten hexafluoride, SiCl₄, AlCl₃, TaI₅, TaF₅, SnI₄, chromyl chloride, copper(II) dialkylamino-2-propoxides, tris[bis(trimethylsilyl)amido]lanthanum, Ga(N₃)₂Et, TiCl₄, praseodymium alkoxide, Pt(C₂H₅C₅H₄)(CH₃)₃, Pt(acac)₂, molybdenum(V) chloride, zinc bis(O-ethylxanthate), CuII(tmhd)₂, Ru(Cp)₂, Ru(EtCp)₂, (2,4-dimethylpentadienyl)(ethylcyclopentadienyl)Ru, tris(2,4-pentanedionato)iridium, Ru(thd)₃, (methylcyclopentadienyl)trimethylplatinum, hexafluoroacetylacetonato(trimethylsilylethylene)copper, Cu(II) (diketiminate)₂, cyclopentadienylallylnickel, Rh(acetylacetonato)₃, Pd(hexafluoroacetonylacetonate)₂, Pd(2,2,6,6-tetramethyl-3,5-heptanedione)₂, methylcyclopentadienyltrimethylplatnium, Ga₂(NMe₂)₆, [(CH₃]₂GaNH₃]₃, bis(2,2,6,6-tetramethyl-3,5-heptanedionato)Sr, Pb(thd)₂, Pb(C₂H₅)₄, (CpCH₃)₃Gd, (Ba(thd)₂), InCl₃ and rare earth precursors with β-diketonate-type ligands including Gd(thd)₃ and Er(thd)₃. Most preferred are the first precursors useful for producing a silicon oxide, titanium oxide, aluminum oxide (commonly referred to as alumina), tantalum oxide, hafnium oxide, zirconium oxide, titanium aluminate, titanium silicate, hafnium aluminate, hafnium silicate, zirconium aluminate, zirconium silicate or boron nitride reaction product.

Useful vaporized or vaporizable second precursors include H₂O (as water vapor), O₂, O₃, nitrous oxide (N₂O), nitric oxide (NO), nitrogen dioxide (NO₂), nitrogen pentoxide (N₂O₅), NH₃, N₂, H₂, diborane, H₂O₂, triphenylborane, H₂S and methane. Ideal characteristics of an ALD precursor include high vapor pressure, thermal stability prior to deposition, ease of handling and transfer, the ability to chemisorb to a substrate surface, aggressive reaction with complementary precursors, non-corrosive to substrate, high purity and low hazard by-products. Both the first and second precursor reactants should be gases at the temperature at which the reactions are conducted. Particularly preferred reactants have vapor pressures of at least about 0.1 Torr or greater at a temperature of about room temperature to about 150° C. The reactants are selected such that they can engage in the reactions that form the desired material at the temperatures stated above. Catalysts may be used to promote the reactions at the required temperatures.

Most commonly, materials deposited by ALD are inorganic. Table 1 below lists examples of suitable coating materials, first precursors and co-reactants (i.e. second precursors).

TABLE 1

| Coating Material | | Co-Reactant |
|---|---|---|
| (Reaction | | (Second |
| Product) | First Precursor | Precursor) |
| Al₂O₃ | trimethyaluminum, tris(diethylamido)aluminum, | H₂O, O₂, O₃, |
| | tris(ethylmethylamido)aluminum, | N₂O, NO₂, |
| | diethylaluminum ethoxide, aluminum sec- | N₂O₅, H₂O₂ |
| | butoxide, AlCl₃, AlBr₃ | |
| HfO₂ | tetrakis(dimethylamido)hafnium(IV), | H₂O, O₂, O₃, |
| | tetrakis(ethylmethylamido)hafnium(IV), | N₂O, NO₂, |
| | hafnium(IV) chloride, hafnium(IV) tert-butoxide, | N₂O₅, H₂O₂ |
| | tetrakis(diethylamido)hafnium(IV) | |
| ZrO₂ | tetrakis(diethylamido)zirconium(IV), | H₂O, O₂, O₃, |
| | tetrakis(dimethylamido)zirconium(IV), | N₂O, NO₂, |
| | tetrakis(ethylmethylamido)zirconium(IV), | N₂O₅, H₂O₂ |
| | zirconium tetrakis(2,2,6,6-tetramethyl-3,5- | |
| | heptanedionate) | |
| TiO₂ | TiCl₄, TiI₄, TiBr₄, titanium isopropyloxide, | H₂O, O₂, O₃, |
| | bis(diethylamino)bis(diisopropylamino)titanium(IV), | N₂O, NO₂, |
| | tetrakis(diethylamido)titanium(IV), | N₂O₅, H₂O₂ |
| | tetrakis(dimethylamido)titanium(IV), | |
| | tetrakis(ethylmethylamido)titanium(IV) | |
| Ta₂O₅ | TaI₅, TaF₅, pentakis(dimethylamino)tantalum, | H₂O, O₂, O₃, |
| | tris(diethylamido)(tert-butylimido)tantalum | N₂O, NO₂, |
| | | N₂O₅, H₂O₂ |
| SiO₂ | dimethoxydimethylsilane, methylsilane, disilane, | H₂O, O₂, O₃, |
| | 2,4,6,8-tetramethylcyclotetrasiloxane, tris(tert- | N₂O, NO₂, |
| | butyoxy)silanol, SiCl₄, SiH₄ | N₂O₅, H₂O₂ |
| WO₃ | tungsten hexacarbonyl, tungsten hexafluoride, | H₂O, O₂, O₃, |
| | bis(cyclopentadienyl)tungsten dichloride, | N₂O, NO₂, |
| | bis(cyclopentadienyl)tungsten dihydride, bis(tert- | N₂O₅, H₂O₂ |
| | butylimido)bis(dimethylamido)tungsten(VI) | |
| FeO | bis(N,N′-di-tert-butylacetamidinato)iron(II) | H₂O, O₂, O₃, |
| | | N₂O, NO₂, |
| | | N₂O₅, H₂O₂ |
| MoO₃ | molybdenum hexacarbonyl, molybdenum | H₂O, O₂, O₃, |
| | hexafluoride, molybdenum(V) chloride | N₂O, NO₂, |
| | | N₂O₅, H₂O₂ |
| Y₂O₃ | tris(N,N-bis(trimethylsilyl)amide)yttrium, Cp₃Y, | H₂O, O₂, O₃, |
| | (CpCh₃)₃Y, Y(thd)₃ | N₂O, NO₂, |
| | | N₂O₅, H₂O₂ |
| NiO | cyclopentadienylallylnickel, bis(N,N′- | H₂O, O₂, O₃, |
| | diisopropylacetamidinato)nickel(II), | N₂O, NO₂, |
| | bis(methylcyclopentadienyl)nickel(II) | N₂O₅, H₂O₂ |
| Rare earth | rare earth precursors with “β-diketonate-type” | H₂O, O₂, O₃, |
| oxide | ligands, (CpCH₃)₃Gd, | N₂O, NO₂, |
| | tris[bis(trimethylsilyl)amido]lanthanum, | N₂O₅, H₂O₂ |
| | praseodymium alkoxide | |
| V₂O₅ | bis(cyclopentadienyl)vanadium(II), vanadyl | H₂O, O₂, O₃, |
| | acetylacetonate | N₂O, NO₂, |
| | | N₂O₅, H₂O₂ |
| Co₂O₃ | bis(N,N′-diisopropylacetamidinato)cobalt(II), | H₂O, O₂, O₃, |
| | bis(pentamethylcyclopentadienyl)cobalt(II), | N₂O, NO₂, |
| | bis(ethylcyclopentadienyl)cobalt(II), cobalt | N₂O₅, H₂O₂ |
| | tris(2,2,6,6-tetramethyl-3,5-heptanedionate) | |
| MgO | bis(cyclopentadienyl)magnesium(II), | H₂O, O₂, O₃, |
| | bis(pentamethylcyclopentadienyl)magnesium(II) | N₂O, NO₂, |
| | | N₂O₅, H₂O₂ |
| Cr₂O₃ | bis(pentamethylcyclopentadienyl)chromium(II), | H₂O, O₂, O₃, |
| | chromyl chloride | N₂O, NO₂, |
| | | N₂O₅, H₂O₂ |
| CuO | hexafluoroacetylacetonato(trimethylsilylethylene)copper, | H₂O, O₂, O₃, |
| | Cu(II) (diketiminate)₂, CuII(tmhd)₂, | N₂O, NO₂, |
| | copper(II) dialkylamino-2-propoxides | N₂O₅, H₂O₂ |
| SrO | bis(2,2,6,6-tetramethyl-3,5-heptanedionato)Sr | H₂O, O₂, O₃, |
| | | N₂O, NO₂, |
| | | N₂O₅, H₂O₂ |
| BaO | Ba(thd)₂ | H₂O, O₂, O₃, |
| | | N₂O, NO₂, |
| | | N₂O₅, H₂O₂ |
| SnO₂ | SnI₄, SnCl₄ | H₂O, O₂, O₃, |
| | | N₂O, NO₂, |
| | | N₂O₅, H₂O₂ |
| ZnO | zinc bis(O-ethylxanthate), zinc acetate | H₂O, O₂, O₃, |
| | | N₂O, NO₂, |
| | | N₂O₅, H₂O₂ |
| Ga₂O₃ | Ga(N₃)₂Et, Ga₂(NMe₂)₆, [(CH₃]₂GaNH₃]₃ | H₂O, O₂, O₃, |
| | | N₂O, NO₂, |
| | | N₂O₅, H₂O₃ |
| In₂O₃ | InCl₃ | H₂O, O₂, O₃, |
| | | N₂O, NO₂, |
| | | N₂O₅, H₂O₄ |
| PbO | Pb(thd)₂, Pb(C₂H₅)₄, | H₂O, O₂, O₃, |
| | | N₂O, NO₂, |
| | | N₂O₅, H₂O₅ |
| Ru | Ru(thd)₃, Ru(Cp)₂, Ru(EtCp)₂, (2,4- | O₂, H₂, NH₃, |
| | dimethylpentadienyl)(ethylcyclopentadienyl)Ru | diborane, |
| | | triphenylborane |
| Ir | tris(2,4-pentanedionato)iridium | O₂, H₂, NH₃, |
| | | diborane, |
| | | triphenylborane |
| Pt | (methylcyclopentadienyl)trimethylplatinum, | O₂, H₂, NH₃, |
| | Pt(C₂H₅C₅H₄) (CH₃)₃, Pt(acac)₂, | diborane, |
| | methylcyclopentadienyltrimethylplatnium | triphenylborane |
| Pd | Pd(hexafluoroacetonylacetonate)₂, Pd(2,2,6,6, | O₂, H₂, NH₃, |
| | | diborane, |
| | tetramethyl-3,5heptanedione)₂, Pb(thd)₂ | triphenylborane |
| Rh | Rh(acetylacetonato)₃ | O₂, H₂, NH₃, |
| | | diborane, |
| | | triphenylborane |
| Rh | Rh(acetylacetonato)₃, CpRh(CO)₂ | O₂, H₂, NH₃, |
| | | diborane, |
| | | triphenylborane |
| Fe | bis(N,N′-di-tert-butylacetamidinato)iron(II) | H₂, NH₃, |
| | | diborane, |
| | | triphenylborane |
| Ni | cyclopentadienylallylnickel, bis(N,N′- | H₂, NH₃, |
| | diisopropylacetamidinato)nickel(II), | diborane, |
| | bis(methylcyclopentadienyl)nickel(II), | triphenylborane |
| Co | bis(N,N′-diisopropylacetamidinato)cobalt(II), | H₂, NH₃, |
| | bis(pentamethylcyclopentadienyl)cobalt(II), | diborane, |
| | bis(ethylcyclopentadienyl)cobalt(II), cobalt | triphenylborane |
| | tris(2,2,6,6-tetramethyl-3,5-heptanedionate) | |
| Cr | bis(pentamethylcyclopentadienyl)chromium(II), | H₂, NH₃, |
| | chromyl chloride | diborane, |
| | | triphenylborane |
| Sn | SnI₄, SnCl₄ | H₂, NH₃, |
| | | diborane |
| | | triphenylborane |
| Zn | zinc bis(O-ethylxanthate), zinc acetate | H₂, NH₃, |
| | | diborane, |
| | | triphenylborane |
| W | tungsten hexafluoride | Si₂H₆ |

Specifically, Table 1 gives examples of metal-containing precursors and the co-reactants (second precursor) for metal oxide and metal ALD coating formation. For nitride ALD coating deposition, nitrogen containing precursors NH₃ and NH₂NH₂ are preferred. For carbide formation, carbon containing co-reactants including methane are preferred. For sulfide formation, sulfur containing co-reactants including H₂S are preferred. For silicide formation, silicon containing co-reactants including SiH₄, Si₂H₆, dimethoxydimethylsilane, methylsilane, disilane, 2,4,6,8-tetramethylcyclotetrasiloxane, tris(tert-butyoxy)silanol and SiCl₄ are preferred. For boride formation, boron containing co-reactants including borane and diborane are preferred. For fluoride formation, fluorine containing co-reactants including HF and SiF₄ are preferred.

In one preferred embodiment, aluminum oxide is deposited onto a substrate by ALD by conducting two half-reactions with TMA as the first precursor and water vapor as the second precursor, via the following reaction mechanism:

—Al—OH(s)+Al(CH₃)₃(g)→Al—O—Al(CH₃)₂(s)+CH₄(g) (reaction 1)

—O—Al(CH₃)₂(s)+H₂O—Al—OH(s)+CH₄(g) (reaction 2)

These reactions are preferably conducted at about room temperature to about 200° C. to effectively react with and chemisorb to the fiber or fabric surfaces, forming an aluminum oxide monolayer. One monolayer of aluminum oxide has a thickness of approximately 1 Å (0.1 nm).

In a method of depositing tantalum oxide onto a substrate by ALD, two half-reactions are conducted with pentakis(dimethylamino)tantalum as the first precursor and H₂O as the second precursor. In the first half-reaction, the Ta(NMe₂)₅ chemically adsorbs to the hydroxyl group terminated surface with the simultaneous breaking of Ta—N bonds and the formation of Ta—O bonds. This step forms one to four tantalum-oxygen bonds. In the second precursor pulse step, water reacts with the chemically adsorbed tantalum amides to regenerate the surface hydroxyls by cleaving the remaining Ta—N bonds. Dimethylamine is released as a byproduct in both steps.

These reactions are preferably conducted at about room temperature to about 200° C. to effectively react with and chemisorb to the fiber or fabric surfaces, forming a tantalum oxide monolayer. The growth rate of tantalum oxide is approximately 1 Å/cycle (0.1 nm).

The precursors forming the above reaction products may also include one or more different elemental based vaporizable precursor compounds depending on the structural and composition requirements of the thin films. For example, the introduction of different metal-based vaporizable precursors would result in the formation of doped, alloyed or nanolaminated coatings. Different metal-based vaporizable precursors may also be co-pulsed into the reaction vessel and adsorbed onto a substrate surface for doped or alloyed coating formation. Alternating reactant exposure creates unique properties of deposited coatings. The coating thickness is determined simply by number of deposition cycles, precursors are saturatively chemisorbed forming stoichiometric films with large area uniformity and 3D conformality, the coatings are relatively insensitive to dust and intrinsic deposition uniformity and small source size allows for easy scaling. Nanolaminates and mixed oxides possible, low temperature deposition is possible, and ALD is a gentle deposition process for sensitive substrates.

As discussed above, the substrates of the invention include single, preferably non-semiconductive polymeric fibers or a plurality of polymeric, preferably non-semiconductive fibers, where a plurality of fibers may be present in the form of a woven fabric, a non-woven fabric or a yarn. As is well known in the art, a woven ballistic resistant fabric may be formed using any of many conventional techniques using any fabric weave such as plain weave, crowfoot weave, basket weave, satin weave, twill weave and the like. Plain weave is most common.

A variety of woven fabrics are commercially available and differ based on their fiber type and weave characteristics, such as weave style, the tightness of the weave and the fabric pick count. For example, for 1200 denier polyethylene fibers such as SPECTRA® 900 fibers produced by Honeywell International Inc., preferred woven fabrics are plain weave fabrics with about 15×15 ends/inch (about 5.9 ends/cm) to about 45×45 ends/inch (17.7 ends/cm) are preferred. More preferred are plain weave fabrics having from about 17×17 ends/inch (6.7 ends/cm) to about 23×23 ends/inch (9.0 ends/cm). For 650 denier SPECTRA® 900 polyethylene fibers, plain weave fabrics having from about 20×20 ends/inch (7.9 ends/cm) to about 40×40 ends/inch (16 ends/cm) are preferred. For 215 denier SPECTRA® 1000 polyethylene fibers, plain weave fabrics having from about 40×40 ends/inch (16 ends/cm) to about 60×60 ends/inch (24 ends/cm) are preferred. In a most preferred embodiment of the invention, the ballistic resistant fabrics of the invention comprise woven SPECTRA® fabric of fabric style 903, which has a plain weave construction, a pick count of 21×21 ends/inch (ends/2.54 cm) and an areal weight of 7 oz/yd² (217 g/m² (gsm)). Also preferred is woven SPECTRA® fabric style 960 (375 denier SPECTRA® 1000 fibers), which has a plain weave construction, a pick count of 35×35 ends/inch, a fabric thickness of 0.007″ (0.18 mm) and an areal weight of 3.2 oz/yd² (108 gsm). For superior ballistic performance, the individual fabric layers used herein also preferably have a compact cover percentage of at least about 75%, more preferably at least about 80% and most preferably at least about 85%. The compact cover percentage of a fabric layer can be defined as the amount of fiber coverage in a 1 inch (2.54 cm)×1 inch (2.54 cm) fabric area. For a fabric composed of 1200 denier fibers, the maximum number of fibers that can fit into a 1″×1″ area is 24×24 in the warp and fill directions. The compact cover percentage is the percentage of fibers that fill the available fiber area. For example, woven fabric style 903 is comprised of 1200 denier fibers, S900 SPECTRA fibers, having a plain weave with a pick count of 21×21 ends/inch. Compared to a maximum of 24×24 ends/inch, fabric style 903 has a compact cover percent of 21 divided by 24, or approximately 87%. For woven fabrics, the tighter the weave, the higher the pick count. Fabrics with a looser weave, such as open mesh fabrics or scrims, have much lower pick counts. Fabric style 903 is distinguished from, for example, fabric style 902 which has a pick count of 17×17 and a compact cover percentage of about 71%. For the purposes of this invention, tightly woven fabrics are most preferred.

Non-woven fabrics may have a variety of constructions as well, including fibers that are randomly oriented, as with a felt, or arranged in an organized array, such as a parallel array. An “array” describes an orderly arrangement of fibers or yarns, and a “parallel array” describes an orderly, unidirectional parallel arrangement of fibers or yarns aligned so that they are substantially parallel to each other along a common fiber direction. Non-woven fabrics may include one or more fiber layers (or “plies”), where a fiber “layer” describes a planar arrangement of woven or non-woven fibers or yarns, and where multiple fiber layers are preferably united by consolidation to form a single layer consolidated structure.

In the preferred embodiments of the invention, a non-woven fabric preferably comprises a single-layer, consolidated network of fibers wherein the fibers are at least partially covered with and an elastomeric or rigid polymeric composition, which polymeric composition is also referred to in the art as a polymeric matrix composition. A fiber “network” denotes a plurality of interconnected fiber or yarn layers. As used herein, the term “interconnected” describes a reciprocal connection of the multiple layers or multiple panels of the invention, such that the structure functions as a single unit. A “consolidated network” describes a consolidated (merged) combination of fiber layers with a polymeric composition. As used herein, a “single layer” structure refers to monolithic structure composed of one or more individual fiber layers that have been stacked together and consolidated into a single unitary structure. In general, a “fabric” may relate to either a woven or non-woven material.

As is conventionally known in the art, excellent ballistic resistance is achieved when individual fiber layers are cross-plied such that the fiber alignment direction of one layer is rotated at an angle with respect to the fiber alignment direction of another layer. Accordingly, successive layers of such unidirectionally aligned fibers are preferably rotated with respect to a previous layer. An example is a two layer (two ply) structure wherein adjacent layers (plies) are aligned in a 0°/90° orientation, where each individual non-woven ply is also known as a “unitape”. However, adjacent layers can be aligned at virtually any angle between about 0° and about 90° with respect to the longitudinal fiber direction of another layer. For example, a five ply non-woven structure may have plies at a 0°/45°/90°/45°/0° orientation or at other angles. In the preferred embodiment of the invention, only two individual non-woven plies, cross-plied at 0° and 90°, are consolidated into a single layer network. However, it should be understood that the single-layer consolidated networks of the invention may generally include any number of cross-plied (or non-cross-plied) plies. The greater the number of layers that are merged into a consolidated structure translates into greater ballistic resistance, but also greater weight. Most typically, the single-layer consolidated networks include from 1 to about 6 plies, but may include as many as about 10 to about 20 plies as may be desired for various applications. Such rotated unidirectional alignments are described, for example, in U.S. Pat. Nos. 4,457,985; 4,748,064; 4,916,000; 4,403,012; 4,623,573; and 4,737,402. Preferably, the fabrics of the invention are selected to have superior ballistic penetration resistance against high energy ballistic threats, including bullets and high energy fragments, such as shrapnel.

As described above, each ply in a single layer consolidated structure includes fibers that are coated with a polymeric matrix composition. For the purposes of the invention, the application of the matrix composition to the fibers must be conducted after the atomic layer deposition of the encapsulation layer. This is important because the first precursor materials may not be reactive with surface molecules of the polymeric matrix composition. Thus, a polymeric matrix composition is applied onto the atomic layer deposited encapsulation layer. A polymeric matrix composition may also be similarly applied onto woven fabrics, where the matrix polymer is applied onto the encapsulation layer. Further, a plurality of woven fabrics may also be coated with a polymeric matrix composition and consolidated by molding under pressure into a monolithic structure. Each layer of woven fabric equals one ply.

A variety of polymeric composition (polymeric matrix composition) materials, including both low modulus, elastomeric materials and high modulus, rigid materials. Suitable polymeric composition materials non-exclusively include low modulus, elastomeric materials having an initial tensile modulus less than about 6,000 psi (41.3 MPa), and high modulus, rigid materials having an initial tensile modulus at least about 300,000 psi (2068 MPa), each as measured at 37° C. by ASTM D638. As used herein throughout, the term tensile modulus means the modulus of elasticity as measured by ASTM 2256 for a fiber and by ASTM D638 for a polymeric matrix composition material.

An elastomeric polymeric matrix composition may comprise a variety of materials. The preferred elastomeric polymeric composition comprises a low modulus elastomeric material. For the purposes of this invention, a low modulus elastomeric material has a tensile modulus, measured at about 6,000 psi (41.4 MPa) or less according to ASTM D638 testing procedures. Preferably, the tensile modulus of the elastomer is about 4,000 psi (27.6 MPa) or less, more preferably about 2400 psi (16.5 MPa) or less, more preferably 1200 psi (8.23 MPa) or less, and most preferably is about 500 psi (3.45 MPa) or less. The glass transition temperature (Tg) of the elastomer is preferably less than about 0° C., more preferably the less than about −40° C., and most preferably less than about −50° C. The elastomer also has a preferred elongation to break of at least about 50%, more preferably at least about 100% and most preferably has an elongation to break of at least about 300%.

A wide variety of materials and formulations having a low modulus may be utilized as the polymeric matrix composition. Representative examples include polybutadiene, polyisoprene, natural rubber, ethylene-propylene copolymers, ethylene-propylene-diene terpolymers, polysulfide polymers, polyurethane elastomers, chlorosulfonated polyethylene, polychloroprene, plasticized polyvinylchloride, butadiene acrylonitrile elastomers, poly(isobutylene-co-isoprene), polyacrylates, polyesters, polyethers, fluoroelastomers, silicone elastomers, copolymers of ethylene, and combinations thereof, and other low modulus polymers and copolymers curable below the melting point of the polyolefin fiber. Also preferred are blends of different elastomeric materials, or blends of elastomeric materials with one or more thermoplastics. The polymeric composition may also include fillers such as carbon black or silica, may be extended with oils, or may be vulcanized by sulfur, peroxide, metal oxide or radiation cure systems as is well known in the art.

Particularly useful are block copolymers of conjugated dienes and vinyl aromatic monomers. Butadiene and isoprene are preferred conjugated diene elastomers. Styrene, vinyl toluene and t-butyl styrene are preferred conjugated aromatic monomers. Block copolymers incorporating polyisoprene may be hydrogenated to produce thermoplastic elastomers having saturated hydrocarbon elastomer segments. The polymers may be simple tri-block copolymers of the type A-B-A, multi-block copolymers of the type (AB)ₙ (n=2-10) or radial configuration copolymers of the type R-(BA)ₓ (x=3-150); wherein A is a block from a polyvinyl aromatic monomer and B is a block from a conjugated diene elastomer. Many of these polymers are produced commercially by Kraton Polymers of Houston, Tex. and described in the bulletin “Kraton Thermoplastic Rubber”, SC-68-81. The most preferred polymeric composition polymer comprises styrenic block copolymers sold under the trademark Kraton® commercially produced by Kraton Polymers. The most preferred low modulus polymeric matrix composition comprises a polystyrene-polyisoprene-polystrene-block copolymer.

Preferred high modulus, rigid polymeric composition materials useful herein include materials such as a vinyl ester polymer or a styrene-butadiene block copolymer, and also mixtures of polymers such as vinyl ester and diallyl phthalate or phenol formaldehyde and polyvinyl butyral. A particularly preferred rigid polymeric composition material for use in this invention is a thermosetting polymer, preferably soluble in carbon-carbon saturated solvents such as methyl ethyl ketone, and possessing a high tensile modulus when cured of at least about 1×10⁶ psi (6895 MPa) as measured by ASTM D638. Particularly preferred rigid polymeric composition materials are those described in U.S. Pat. No. 6,642,159, which is incorporated herein by reference.

The rigidity, impact and ballistic properties of the articles formed from the fabrics of the invention are affected by the tensile modulus of the polymeric composition polymer. For example, U.S. Pat. No. 4,623,574 discloses that fiber reinforced composites constructed with elastomeric matrices having tensile moduli less than about 6000 psi (41,300 kPa) have superior ballistic properties compared both to composites constructed with higher modulus polymers, and also compared to the same fiber structure without a polymeric matrix composition. However, low tensile modulus polymeric matrix composition polymers also yield lower rigidity composites. Further, in certain applications, particularly those where a composite must function in both anti-ballistic and structural modes, there is needed a superior combination of ballistic resistance and rigidity. Accordingly, the most appropriate type of polymeric composition polymer to be used will vary depending on the type of article to be formed from the fabrics of the invention. In order to achieve a compromise in both properties, a suitable polymeric matrix composition may combine both low modulus and high modulus materials to form a single polymeric matrix composition.

In the preferred embodiments of the invention, each ply of woven fabric, each felt ply, each non-woven fabric ply, or each consolidated single-layer structure including woven or non-woven plies (or both) comprises a fiber content of at least about 65% by weight, more preferably at least about 70% by weight, more preferably at least about 75%, and most preferably at least about 80% by weight of the total combined weight of the ALD coated composite structure. The composite structure consists of the fiber or fibers, plus the encapsulation material, plus the optional polymeric matrix composition and any additives therein.

Preferably, the proportion of the polymeric matrix composition making up the composites preferably comprises from about 0% to about 35% by weight based on the total weight of each composite, more preferably from about 11% to about 22% by weight and most preferably from about 7% to about 15% by weight of the ALD coated composite structure. Preferably, the proportion of the encapsulation layer making up the composites preferably comprises from about 0.001% to about 1% by weight based on the total weight of the composite, more preferably from about 0.001% to about 0.5% by weight and most preferably from about 0.001% to about 0.1% by weight of the ALD coated composite structure. Typically, the weight change from the addition of the nanometer-size thick encapsulation layers is too small to be consistently measured, which is a benefit of conformal coating with high thickness uniformity. While such proportions are preferred, it is to be understood that composites having other proportions may be produced to satisfy a particular need and yet fall within the scope of the present invention.

When a plurality of stacked fibrous layers are consolidated, they are united into a monolithic structure by the application of heat and pressure, forming the single-layer, consolidated network. The consolidation merges the fibers and the polymeric matrix composition of each component fibrous layer. The non-woven fiber networks can be constructed using well known methods, such as by the methods described in U.S. Pat. No. 6,642,159. A consolidated network may also comprise a plurality of yarns that are coated with such a polymeric matrix composition, formed into a plurality of layers and consolidated into a fabric. As stated above, non-woven fiber networks may also comprise a felted structure which is formed using conventionally known techniques, comprising fibers in a random orientation embedded in a suitable polymeric composition that are matted and compressed together.

A polymeric matrix composition may be applied to a fiber in a variety of ways which are well known in the art, and the term “coated” is not intended to limit the method by which the polymeric composition is applied onto the fiber surface or surfaces. For example, the polymeric composition may be applied in solution or emulsion form by spraying or roll coating the composition onto fiber surfaces, or by dipping the fibers or fabric ply into a bath of a solution containing the polymeric composition dissolved in a suitable solvent. Another method is to apply a neat polymer of the coating material to fibers either as a liquid, a sticky solid or particles in suspension or as a fluidized bed. When a polymeric matrix composition is applied, the preferably covers 100% of the fiber surface area on top of the encapsulation layer.

The application of the polymeric composition is conducted prior to consolidating the fiber layers, and any appropriate method of applying the polymeric composition onto the fiber surfaces may be utilized. Accordingly, the fibers of the invention may be coated on, impregnated with, embedded in, or otherwise applied with a polymeric composition by applying the composition to the fibers and then optionally consolidating the composition-fibers combination to form a composite. As stated above, by “consolidating” it is meant that the polymeric composition material and each individual fiber layer are combined into a single unitary layer. Consolidation can occur via drying, cooling, heating, pressure or a combination thereof. The term “composite” refers to consolidated combinations of fibers with the polymeric matrix composition. The term “matrix” as used herein is well known in the art, and is used to represent a polymeric binder material that binds the fibers together after consolidation. Generally, a polymeric matrix composition coating is necessary to effectively consolidate a plurality of fabric plies.

Multiple fabric plies are preferably consolidated by molding under heat and pressure in a suitable molding apparatus. Generally, the plies are molded at a pressure of from about 50 psi (344.7 kPa) to about 5000 psi (34470 kPa), more preferably about 100 psi (689.5 kPa) to about 1500 psi (10340 kPa), most preferably from about 150 psi (1034 kPa) to about 1000 psi (6895 kPa). The multiple plies may alternately be molded at higher pressures of from about 500 psi (3447 kPa) to about 5000 psi, more preferably from about 750 psi (5171 kPa) to about 5000 psi and more preferably from about 1000 psi to about 5000 psi. The molding step may take from about 4 seconds to about 45 minutes. Preferred molding temperatures range from about 200° F. (∞93° C.) to about 350° F. (˜177° C.), more preferably at a temperature from about 200° F. to about 300° F. (˜149° C.) and most preferably at a temperature from about 200° F. to about 280° F. (˜121° C.). Suitable molding temperatures, pressures and times will generally vary depending on the type of polymeric composition type, polymeric composition content, and type of fiber. The pressure under which the fabrics of the invention are molded has a direct effect on the stiffness or flexibility of the resulting molded product. Particularly, the higher the pressure at which the fabrics are molded, the higher the stiffness, and vice-versa. In addition to the molding pressure, the quantity, thickness and composition of the fabric layers, polymeric composition type and optional polymer film also directly affects the stiffness of the articles formed from the inventive fabrics.

Consolidation may alternately be conducted with heat in an autoclave, as is conventionally known in the art. If heated, it is possible that the polymeric matrix composition can be caused to stick or flow without completely melting. However, generally, if the polymeric composition material is caused to melt, relatively little pressure is required to form the composite, while if the polymeric composition material is only heated to a sticking point, more pressure is typically required. Consolidation in an autoclave may generally take from about 10 seconds to about 24 hours and suitable temperatures, pressures and times are generally dependent on the type of polymeric matrix composition, polymeric matrix content and type of fiber.

Rather than consolidating, a plurality of fabric plies may be attached by other means. Each of the plies may be initially stacked or adjoined in a non-bonded array, followed by subsequently interconnecting all of the plies together to form a bonded array. Most preferably, multi-ply composites are interconnected such that they are reciprocally connected to function as a single unit. Methods of bonding are well known in the art, and include stitching, quilting, bolting, adhering with adhesive materials, and the like. Preferably, said plurality of layers are attached by stitching together at edge areas of the layers, such as by tack stitching.

The number of fabric plies forming a ballistic resistant article will vary depending upon the desired use of the article. For example, in body armor vests for military applications, in order to form an article composite that achieves a desired 1.0 pound per square foot areal density (4.9 kg/m²), a total of at 22 individual plies may be required, wherein the plies may be woven, knitted, felted or non-woven fabrics formed from the high-strength fibers described herein, and the layers may or may not be attached together. In another embodiment, body armor vests for law enforcement use may have a number of layers based on the National Institute of Justice (NIJ) Threat Level. For example, for an NIJ Threat Level IIIA vest, there may also be a total of 22 layers. For a lower NIJ Threat Level, fewer layers may be employed.

The thickness of the individual fabric plies will correspond to the thickness of the individual fibers. Accordingly, a preferred woven fabric will have a preferred thickness of from about 25 μm to about 500 μm, more preferably from about 75 μm to about 385 μm and most preferably from about 125 μm to about 255 μm. A preferred single-layer, consolidated network will have a preferred thickness of from about 12 μm to about 500 μm, more preferably from about 75 μm to about 385 μm and most preferably from about 125 μm to about 255 μm. The encapsulation layer preferably has a thickness of from about 0.5 nm to about 1000 nm, more preferably from about 5 nm to about 500 nm and most preferably from about 10 nm to about 100 nm. While such thicknesses are preferred, it is to be understood that other film thicknesses may be produced to satisfy a particular need and yet fall within the scope of the present invention. Soft armor articles formed in accordance with the invention have a preferred areal density of from about 0.25 lb/ft² (psf) (1.22 kg/m² (ksm)) to about 2.0 psf (9.76 ksm), more preferably from about 0.5 psf (2.44 ksm) to about 1.5 psf (7.32 ksm), and most preferably from about 0.75 psf (3.66 ksm) to about 1.25 psf (6.1 ksm). Hard armor articles have a preferred areal density of from about 0.25 lb/ft² (psf) (1.22 kg/m² (ksm)) to about 6.0 psf (29.28 ksm), more preferably from about 0.5 psf (2.44 ksm) to about 4.0 psf (19.52 ksm) and most preferably from about 0.75 psf (3.66 ksm) to about 2.00 psf (9.76 ksm).

The ALD coated fabrics of the invention may be used in various applications to form a variety of different ballistic resistant articles using well known techniques. For example, suitable techniques for forming ballistic resistant articles are described in, for example, U.S. Pat. Nos. 4,623,574, 4,650,710, 4,748,064, 5,552,208, 5,587,230, 6,642,159, 6,841,492 and 6,846,758. They are particularly useful for the formation of flexible, soft armor articles, including garments such as vests, pants, hats, or other articles of clothing, and covers or blankets, used by military personnel to defeat a number of ballistic threats, such as 9 mm full metal jacket (FMJ) bullets and a variety of fragments generated due to explosion of hand-grenades, artillery shells, Improvised Explosive Devices (IED) and other such devises encountered in military and peace keeping missions. As used herein, “soft” or “flexible” armor is armor that does not retain its shape when subjected to a significant amount of stress and is incapable of being free-standing without collapsing.

They are also useful for the formation of rigid, hard armor articles. By “hard” armor is meant an article, such as helmets, panels for military vehicles, or protective shields, which have sufficient mechanical strength so that it maintains structural rigidity when subjected to a significant amount of stress and is capable of being freestanding without collapsing. The structures can be cut into a plurality of discrete sheets and stacked for formation into an article or they can be formed into a precursor which is subsequently used to form an article. Such techniques are well known in the art.

Garments of the invention may be formed through methods conventionally known in the art. Preferably, a garment may be formed by adjoining the ballistic resistant articles of the invention with an article of clothing. For example, a vest may comprise a generic fabric vest that is adjoined with the ballistic resistant structures of the invention, whereby the inventive articles are inserted into strategically placed pockets. As used herein, the terms “adjoining” or “adjoined” are intended to include attaching, such as by sewing or adhering and the like, as well as un-attached coupling or juxtaposition with another fabric, such that the ballistic resistant articles may optionally be easily removable from the vest or other article of clothing. Articles used in forming flexible structures like flexible sheets, vests and other garments are preferably formed from using a low tensile modulus polymeric matrix composition. Hard articles like helmets and armor are preferably formed using a high tensile modulus polymeric matrix composition.

The application of an atomic layer deposited encapsulation layer, such as an ALD layer of aluminum oxide, has been found to improve many properties of ballistic resistant fabrics. Bullet/fragment-fabric interaction is directly affected by fiber/surface properties. For example, the atomic layer deposited encapsulation layer improves fabric properties including fiber mobility, which is the ease of fibers moving out of the way of the projectile and the degree of the fiber engagement by the projectile. The encapsulation layer increases the fiber coefficient of friction, thus reducing fiber transverse mobility without significantly increasing the weight of the fabric. SPECTRA® fibers, for example, have a relatively low coefficient of friction and engages projectiles better with the ALD coating. The encapsulation layer increases fiber surface hardness that affects resistance to fiber failure through contact stresses, as well as fiber thermal conductivity, heat dissipation and protection of fiber load-bearing properties at the projectile contact area. By increasing surface hardness, contact damage resistance is increased. Thermal conductivity is increased by about 1 to 2 orders of magnitude, thus increasing the time when the low temperature properties of the fibers and fabric are retained.

Additionally, an ALD coating of aluminum oxide has been found to improve the pullout resistance of ALD treated fabrics by 100% compared to those without aluminum oxide. Further, the encapsulation layer forms a barrier to liquids, such as sea water or gasoline, and other harmful environmental conditions that may degrade the fibers and/or fabrics. All of these improvements are achieved while maintaining fiber flexibility with the encapsulation layer firmly attached to the fibers. The encapsulation layer may also improve the short-term flame and heat retardance performance of the fiber. Importantly, a substantial increase in fiber surface friction for increasing ballistic performance against fragments can be achieved with a minimal ALD coating.

The application of an atomic layer deposited encapsulation layer has also been found to improve many properties of non-ballistic resistant fabrics. For example, an ALD coating of an oxide such as TiO₂ may provide a photocatalytic function to reduce the organic contamination on the fabric surfaces by the environment. A semiconductor oxide coating, including but not limited to V₂O₅, SnO₂, WO₃, ZnO, MoO₃, TiO₂, and MnO₂, can provide functionality as a gas sensing layer as a part of a gas sensor device. ALD coating of low and high refractive index materials can also be applied to polymeric fibers and fabrics to form an optical device such as mirror or filter of unique optical signature for function such as friend-foe identification in the hostile environment. An example of such layers would be multiple double layers of Al₂O₃—TiO₂, SiO₂—TiO₂, Al₂O₃—Ta₂O₅, and SiO₂—Ta₂O₅.

The ballistic resistance properties of the inventive fabrics are determined using standard testing procedures that are well known in the art. Particularly, the protective power or penetration resistance of a structure is normally expressed by citing the impacting velocity at which 50% of the projectiles penetrate the composite while 50% are stopped by the shield, also known as the V₅₀ value. As used herein, the “penetration resistance” of an article is the resistance to penetration by a designated threat, such as physical objects including bullets, fragments, shrapnel and the like, and non-physical objects, such as a blast from explosion. For composites of equal areal density, which is the weight of the composite panel divided by the surface area, the higher the V₅₀ the better the resistance of the composite. The ballistic resistant properties of the articles of the invention will vary depending on many factors, particularly the type of fibers used to manufacture the fabrics.

Flexible ballistic armor articles, weighing 1 psf (4.88 ksm), formed herein preferably have a V₅₀ of at least about 2000 feet/second (fps) (610 m/sec) when impacted with a 4 grain Right Circular Cylinder (RCC) projectile. Flexible ballistic armor articles formed herein preferably have a V₅₀ of at least about 1550 feet/second (fps) (472 m/sec) when impacted with a 17 grain Fragment Simulated Projectile (FSP).

The following examples serve to illustrate the invention:

### EXAMPLE 1

Thermal ALD was conducted to deposit tantalum oxide on three samples of SPECTRA® fabric (fabric style 960). Pentakis(dimethylamino)tantalum was used as a tantalum containing organometallic precursor for ALD coating synthesis of Ta₂O₅ in a flow type F-120 SAT ALD reactor. Water was used as a co-reactant and N₂ was used as a purge gas. The pentakis(dimethylamino)tantalum evaporation temperature used during the growth experiments was 105° C. The fabric temperature during the growth was 110° C. The primary gas flow rate was 200 standard cm³/min (sccm) and the secondary gas flow rate was 300 sccm. The pentakis(dimethylamino)tantalum pulse time was 3 seconds followed by a 2 second nitrogen purge. The H₂O pulse time was 1 second followed by a 2 second nitrogen purge. After a predetermined number of cycles (750, 1100 and 2300, respectively) of deposition, Ta₂O₅ was coated on the fabric samples. The Ta₂O₅ coating thickness was estimated based on Ta₂O₅ film growth rate on a silicon wafer. A total of three samples were coated. The estimated Ta₂O₅ film thickness on fabric is 450 Å for 750 cycles, 670 Å for 1100 cycles and 1400 Å for 2300 cycles, for the three samples.

### EXAMPLE 2

Thermal ALD was conducted to deposit aluminum oxide (Al₂O₃) on three samples of SPECTRA® fabric, style 960. Trimethylaluminum was used as an aluminum containing organometallic precursor for ALD coating synthesis of Al₂O₃ in a flow type F-120 SAT ALD reactor. Water was used as a co-reactant and N₂ was used as a purge gas. The trimethylaluminum evaporation temperature used during the growth experiments was 18° C. The fabric temperature during the growth was 110° C. The primary gas flow rate was 300 sccm and the secondary gas flow rate was 200 sccm. The trimethylaluminum pulse time was 1 second followed by a 2 second nitrogen purge. The H₂O pulse time was 1 second followed by a 2 second nitrogen purge. The growth rate of Al₂O₃ on fabric is about 1 Å/cycle as estimated from Al₂O₃ growth rate on Si wafers. The estimated thickness for three samples coated with alumina was 471 Å, 678 Å, and 1445 Å respectively.

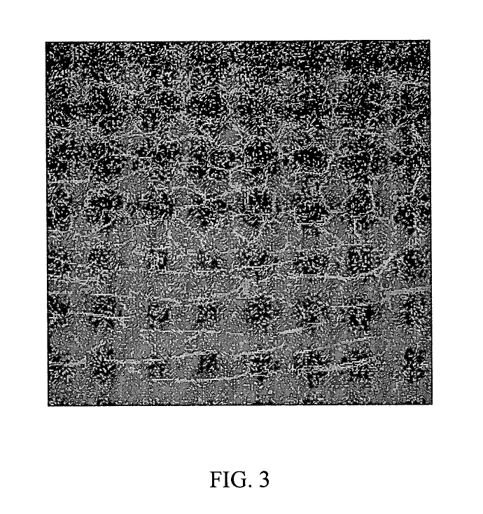

An example of an ALD coated Al₂O₃ film is shown in FIG. 3, which is a scanning electron microscope picture of a cross-section of a coated fabric. The light surface layer is from X-ray mapping of Al from the Al₂O₃, showing uniform coating on an individual fiber surface.

### EXAMPLE 3

Thermal ALD is conducted to deposit tungsten disulfide (WS₂) on SPECTRA® fabric, style 960. Tungsten hexafluoride (WF₆) is used as a tungsten containing organometallic precursor for ALD coating synthesis of tungsten disulfide in a flow type F-120 SAT ALD reactor. Hydrogen sulfide (H₂S) is used as a co-reactant and N₂ is used as a purge gas. Both precursors can be from gas cylinders.

The fabric temperature during the growth is 110° C. The primary gas flow rate is 300 sccm and the secondary gas flow rate is 200 sccm. The WF₆ pulse time is 2 seconds and is followed by a 5 second nitrogen purge. The H₂S pulse time is 2 seconds and is followed by a 25 second nitrogen purge. After a predetermined number cycles of deposition, WS₂ is coated on the fabric.

### EXAMPLE 4

PEALD is conducted to deposit tungsten on SPECTRA® fabric, style 960. Tungsten hexafluoride is used as a tungsten containing organometallic precursor for ALD coating synthesis of tungsten disulfide (WS₂) in a flow type F-120 SAT ALD reactor. Si₂H₆ is used as a co-reactant and N₂ is used as a purge gas. Both precursors can be from gas cylinders. The fabric temperature during the growth is 110° C. The primary gas flow rate is 300 sccm and the secondary gas flow rate is 200 sccm. The WF₆ pulse time is 2 seconds and is followed by a 5 second nitrogen purge. The Si₂H₆ pulse time is 2 seconds and is followed by a 5 second nitrogen purge. Plasma is applied during Si₂H₆ pulse. After a predetermined number cycles of deposition, WS₂ is coated on the fabric.

### EXAMPLE 5

Thermal ALD is conducted to deposit Hf—Al—O alloy oxide onto SPECTRA® fabric, style 960. Tetrakis(ethylmethylamino)hafnium is used as a hafnium containing organometallic precursor and trimethyl aluminium is used as an aluminum containing organometallic precursor for ALD coating synthesis of Hf—Al—O in a flow type F-120 SAT ALD reactor. Water is used as a co-reactant and N₂ is used as a purge gas. Both tetrakis(ethylmethylamino)hafnium and trimethylaluminum are co-injected into the reaction chamber for the metal containing precursor pulse. The fabric temperature during the growth is 110° C. The primary gas flow rate is 200 sccm and the secondary gas flow rate is 300 sccm. The metal containing pulse time is 1 second and is followed by a 2 second nitrogen purge. The H₂O pulse time is 1 second and is followed by a 2 second nitrogen purge. After a predetermined cycles of deposition, an Hf—Al—O alloy coating is coated on the fabric.

### EXAMPLE 6

To demonstrate stab resistance of ALD alumina coated SPECTRA® fabric, a sample of SPECTRA® fabric style 960 was coated with a 1000 Å (100 nm) thick layer of alumina was tested. The tested specimen was stretched in a holder (Instron Model 4502 tester; test method: Compression #06; Loading rate 1.5 in/min) and punched/stabbed by pressing a steel rod (0.21 inch diameter) with a cone tip (sharpness: 60° angle). This type of rod with said cone tip has shape elements similar to a generic projectile fragment and a generic stabbing weapon. The punch penetrated the alumina coated fabric at an average of 171 lbs±16 lbs (3 specimens were tested, punch penetration results were 173 lbs, 153 lbs and 186 lbs, respectively).

### EXAMPLE 7 (COMPARATIVE)

Example 6 was repeated using a standard sample of SPECTRA® fabric style 960 but without the alumina coating. The punch penetrated the uncoated coated fabric at average of 92 lbs±10 lbs (3 specimens were tested, punch penetration results were 81 lbs, 95 lbs and 102 lbs, respectively).

Example 6 and Comparative Example 7 collectively illustrate that a 1000 Å thick atomic layer deposited alumina coating increases the penetration resistance of the sharp probe by 86%.

### EXAMPLE 8

A tensile test was conducted on two samples of ALD alumina coated (coated at 125° C.) SPECTRA® fabric, style 960. The tensile test conducted was the ±45 degree fabric/fiber pull out test method. The coating thickness was 471 Å±20 Å for one sample, and 1445 Å for another sample.

In this test, a strip of SPECTRA® fabric cut out at 45° with respect to the fiber direction is pulled out in tension. The tensile test was conducted using an Instron Model 5500 testing apparatus (loading rate 5 in/min; room temperature 23° C.; humidity 50%; 220 lb. load cell). The grip length was 0.5 inches (1.27 cm). Each fiber is pulled by either upper or lower grips, so they just slide against each other. The strip width is slightly smaller than the gage length. As a result there are no fibers extended across the grips and engaged in tension. The only resistance comes from the fiber mutual sliding. Overall resistance recorded by Instron machine depends on fiber friction. The test is very sensitive to fiber surface properties. The fabrics were inspected for fiber pullout, which is a condition where fibers break or are extracted from the polymeric matrix.

The specimens for the testing were 1 inch (2.54 cm) wide and had a 1.125 inch (2.857 cm) long gage (testing length of the specimen). Both of the ALD coated samples had significantly higher pull out resistance comparing to fabric not coated with alumina. The 471 Å coated sample slipped out of the grip at 150 lbs (68.04 kg), and the 1445 Å coated sample slipped out of the grip at 120 lbs (54.43 kg) without signs of fiber pullout. An uncoated control sample had a max pullout force of 90 lbs (40.82 kg), before breaking.

### EXAMPLE 9

Example 8 was repeated with a sample coated with a 678 Å ALD alumina coating, and was secured with 1 inch (2.45 cm) long grips with emery paper tabs glued thereon with 5 min epoxy glue. Again, uncoated samples had a max pullout force of 90 lbs. The coated sample achieved a load of 220 lbs. without any signs of fiber pullout. Since 220 lbs. was the maximum load for the load cell capability, the test was aborted at 220 lbs. load.

### EXAMPLE 10

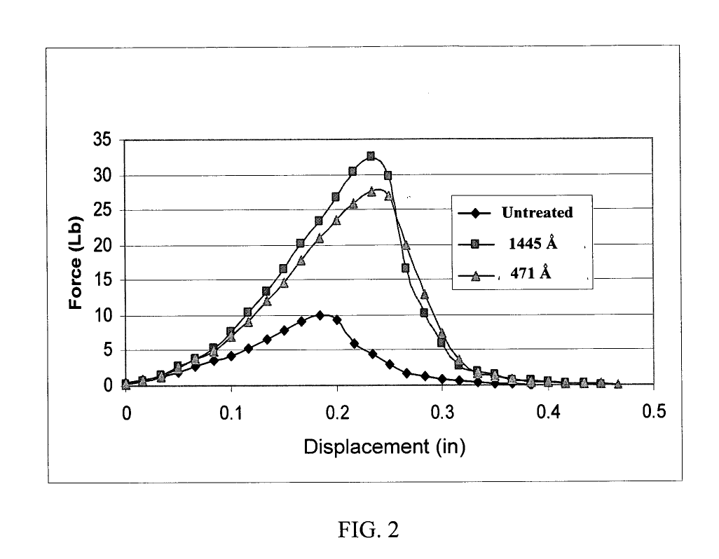

Example 9 was repeated for various samples outlined in Table 2, but the shape of the fabric samples tested was modified to have a specimen size of 0.5 inch width with a 0.7 inch gage length. The grip length of 1 inch and the emery tabs were retained. With these dimensions, the tensile test was conducted and the effect of ALD treatment was determined as follows in Table 2, and the force vs. displacement results for Samples #1, 3 and 4 are plotted in FIG. 2:

TABLE 2

| | Coating Thickness | Max Pullout Force |
|---|---|---|
| Sample | (angstroms) | (lbs) |
| Sample #1 | 471 +/− 9 | 27.5 |
| Sample #2 | 678 +/− 20 | 32.5 |
| Sample #3 | 1445 +/− 12 | 33.5 |
| Sample #4 | none | 11.0 |

From Examples 8-10, it is concluded that an ALD coating of alumina on SPECTRA® fabric style 960 dramatically increases fiber-to-fiber friction. The pullout force increases up to 3 times compared to the untreated control.

A significant difference in the pullout force was not recognized between the samples having the thinnest and the thickest coatings. A three fold increase in the coating thickness led to an increase in the pullout force of about 22%. A illustrated herein, a substantial increase in fiber surface friction for increasing ballistic performance against fragments is achieved with a minimal ALD coating.

### EXAMPLE 11

An alumina encapsulation layer of approximately 400 angstroms (40 nm) thick was coated onto the surfaces of twenty-two 12″×12″ sheets of woven SPECTRAL fabric (fabric style 903; plain weave; pick count: 21×21 ends/inch (2.54 cm); areal weight: 7 oz/yd² (217 gsm)). The twenty-two sheets were clamped together to form a 22 layer shoot pack for ballistic testing, with the target area measuring 10″×10″ after clamping. The shoot pack was tested against a 17 grain Fragment Simulating Projectile (FSP) conforming to the shape, size and weight as per the MIL-P-46593A. V₅₀ ballistic testing was conducted in accordance with the procedures of MIL-STD-662E, and the resulting V₅₀ was measured as 1653 ft/sec. Compared to a V₅₀ of 1472 ft/sec for a similar but uncoated fabric tested under the same conditions, a 25.9% improvement in performance was calculated.

### EXAMPLE 12

An alumina encapsulation layer of approximately 394 angstroms (39.4 nm) thick was coated onto the surfaces of twenty-two 15″×15″ sheets of woven SPECTRA® fabric (fabric style 903 as used in Example 11). The twenty-two sheets were clamped together to form a 22 layer shoot pack for ballistic testing, with the target area measuring 10″×10″ after clamping.

The shoot pack was tested against both a 4 grain Right Circular Cylinder (RCC) and a 17 grain FSP, the 17 grain FSP conforming to the shape, size, and weight as per the MIL-P-46593A. V₅₀ ballistic testing was conducted in accordance with the procedures of MIL-STD-662E. Against the 4 grain RCC, the resulting V₅₀ was measured as 2017 ft/sec. Compared to a V₅₀ of 1982 ft/sec for a similar but uncoated fabric tested under the same conditions against a 4 grain RCC, a 3.5% improvement in performance was calculated. Against the 17 grain FSP, the resulting V₅₀ was measured as 1594 ft/sec. Compared to a V₅₀ of 1533 ft/sec for a similar but uncoated fabric tested under the same conditions against a 17 grain FSP, an 8.1% improvement in performance was calculated. The results are summarized in Table 3 below.

### EXAMPLE 13

An alumina encapsulation layer of approximately 774 angstroms (77.4 nm) thick was coated onto the surfaces of twenty-two 15″×15″ sheets of woven SPECTRA® fabric (fabric style 903 as used in Example 11). The twenty-two sheets were clamped together to form a 22 layer shoot pack for ballistic testing, with the target area measuring 10″×10″ after clamping.

The shoot pack was tested against both a 4 grain RCC and a 17 grain FSP conforming to the shape, size and weight as per the MIL-P-46593A. V₅₀ ballistic testing was conducted in accordance with the procedures of MIL-STD-662E. Against the 4 grain RCC, the resulting V₅₀ was measured as 2074 ft/sec. Compared to a V₅₀ of 1982 ft/sec for a similar but uncoated fabric tested under the same conditions against a 4 grain RCC, a 9.5% improvement in performance was calculated. Against the 17 grain FSP, the resulting V₅₀ was measured as 1570 ft/sec. Compared to a V₅₀ of 1533 ft/sec for a similar but uncoated fabric tested under the same conditions against a 17 grain FSP, an 4.8% improvement in performance was calculated. The results are summarized in Table 3 below.

### EXAMPLE 14

A titanium oxide encapsulation layer of approximately 486 angstroms (48.6 nm) thick was coated onto the surfaces of twenty-two 15″×15″ sheets of woven SPECTRA® fabric (fabric style 903 as used in Example 11). The twenty-two sheets were clamped together to form a 22 layer shoot pack for ballistic testing, with the target area measuring 10″×10″ after clamping.

The shoot pack was tested against both a 4 grain RCC and a 17 grain FSP conforming to the shape, size and weight as per the MIL-P-46593A. V₅₀ ballistic testing was conducted in accordance with the procedures of MIL-STD-662E. Against the 4 grain RCC, the resulting V₅₀ was measured as 2039 ft/sec. Compared to a V₅₀ of 1982 ft/sec for a similar but uncoated fabric tested under the same conditions against a 4 grain RCC, a 5.8% improvement in performance was calculated. Against the 17 grain FSP, the resulting V₅₀ was measured as 1579 ft/sec. Compared to a V₅₀ of 1533 ft/sec for a similar but uncoated fabric tested under the same conditions against a 17 grain FSP, an 6.1% improvement in performance was calculated. The results are summarized in Table 3 below.

TABLE 3

| | Alumina | Alumina | Titanium Oxide | Control |
|---|---|---|---|---|
| | 394 Å | 774 Å | 486 Å | (uncoated) |
| 4 grain V₅₀ | 2017 | 2074 | 2039 | 1982 |
| % improvement | 3.5 | 9.5 | 5.8 | N/A |
| (4 grain V₅₀) | | | | |
| 17 grain V₅₀ | 1594 | 1570 | 1579 | 1533 |
| % improvement | 8.1 | 4.8 | 6.1 | N/A |
| (17 grain V₅₀) | | | | |

Examples 11-14 illustrate the improvement in ballistic performance against fragments when ballistic resistant SPECTRA fabrics are treated with an ALD layer. The highest levels of improvement observed for 4 grain fragments was 9.5% (alumina ALD, 774 Å thickness) and for 17 grain was 8.1% (alumina ALD, 394 Å thickness). Further improvement of this performance is expected through optimization of coating thickness and for tighter weaves among woven fabrics. The tightness of the weave and the friction increase from ALD work symbiotically.

### EXAMPLE 15

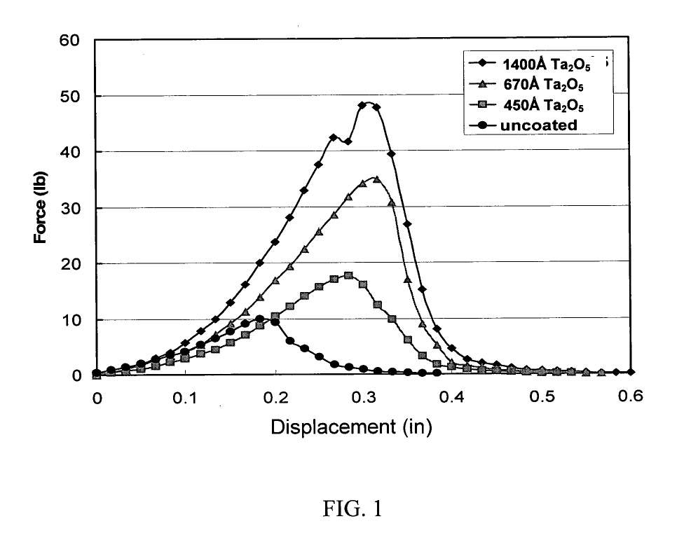

Example 8 was repeated on three samples, each coated with ALD Ta₂O₅ (coated at 110° C.) SPECTRA® fabric, fabric type 903, with coating thicknesses of 1400 Å, 670 Å and 450 Å, respectively, and one sample without Ta₂O₅ coating. The fabrics were inspected for fiber pullout. All of the ALD coated samples had significantly higher pull out resistance comparing to fabric not coated with Ta₂O₅. The specimens for the testing were 0.5 inch (1.27 cm) wide and had a 0.75 inch (1.91 cm) long gage. The grip length was 1 inch (2.54 cm). The results are shown in FIG. 1.

While the present invention has been particularly shown and described with reference to preferred embodiments, it will be readily appreciated by those of ordinary skill in the art that various changes and modifications may be made without departing from the spirit and scope of the invention. It is intended that the claims be interpreted to cover the disclosed embodiment, those alternatives which have been discussed above and all equivalents thereto.

What is claimed is:

1. A method which comprises depositing an encapsulation layer onto a surface of one or more polymeric fibers by atomic layer deposition.

2. The method of claim 1 wherein said one or more polymeric fibers are non-semiconductive.

3. The method of claim 1 wherein said polymeric fibers have a tenacity of about 7 g/denier or more and a tensile modulus of about 150 g/denier or more.

4. The method of claim 1 wherein said polymeric fibers comprise polyolefin fibers, aramid fibers, polybenzazole fibers, polyvinyl alcohol fibers, polyamide fibers, polyethylene terephthalate fibers, polyethylene naphthalate fibers, polyacrylonitrile fibers, liquid crystal copolyester fibers, rigid rod fibers, or a combination thereof.

5. The method of claim 1 wherein said polymeric fibers comprise polyethylene fibers.

6. The method of claim 1 wherein said atomic layer deposition is conducted at a temperature below the melting temperature of the one or more polymeric fibers.

7. The method of claim 1 wherein said encapsulation layer comprises an inorganic material.

8. The method of claim 1 wherein said encapsulation layer comprises silicon oxide, titanium oxide, aluminum oxide, tantalum oxide, hafnium oxide, zirconium oxide, titanium aluminate, titanium silicate, hafnium aluminate, hafnium silicate, zirconium aluminate, zirconium silicate, boron nitride or a combination thereof.

9. The method of claim 1 further comprising subsequently applying a polymeric matrix composition onto the encapsulation layer.

10. The method of claim 1 wherein an encapsulation layer is deposited onto the surfaces of a plurality of polymeric fibers by atomic layer deposition, wherein said fibers are woven together prior to said atomic layer deposition of the encapsulation layer.

11. The method of claim 1 wherein an encapsulation layer is deposited onto the surfaces of a plurality of polymeric fibers by atomic layer deposition, and subsequently forming said plurality of fibers into a fabric.

12. The method of claim 9 wherein an encapsulation layer is deposited onto the surfaces of a plurality of polymeric fibers by atomic layer deposition, and subsequently applying a polymeric matrix composition onto the encapsulation layer, and thereafter forming said plurality of fibers into a fabric.

13. The method of claim 1 wherein said encapsulation layer has a thickness of less than about 1000 nm.

14. A fabric comprising a plurality of non-semiconductive polymeric fibers arranged in an array, said fibers having an atomic layer deposited encapsulation layer thereon.

15. The fabric of claim 14 wherein said one or more polymeric fibers are non-semiconductive.

16. The fabric of claim 14 which comprises a ballistic resistant fabric wherein said polymeric fibers have a tenacity of about 7 g/denier or more and a tensile modulus of about 150 g/denier or more.

17. The fabric of claim 14 which comprises a woven fabric.

18. The fabric of claim 14 which comprises a non-woven fabric, wherein said polymeric fibers further include a polymeric matrix composition on said encapsulation layer.

19. The fabric of claim 14 wherein said polymeric fibers comprise polyolefin fibers, aramid fibers, polybenzazole fibers, polyvinyl alcohol fibers, polyamide fibers, polyethylene terephthalate fibers, polyethylene naphthalate fibers, polyacrylonitrile fibers, liquid crystal copolyester fibers, rigid rod fibers, or a combination thereof.

20. The fabric of claim 14 wherein said encapsulation layer comprises an inorganic material.

21. The fabric of claim 14 wherein said encapsulation layer comprises silicon oxide, titanium oxide, aluminum oxide, tantalum oxide, hafnium oxide, zirconium oxide, titanium aluminate, titanium silicate, hafnium aluminate, hafnium silicate, zirconium aluminate, zirconium silicate, boron nitride or a combination thereof.

22. The fabric of claim 14 wherein said encapsulation layer has a thickness of less than about 1000 nm.

23. An article formed from the fabric of claim 14.

24. An article formed from the fabric of claim 18.
